(19) United States
(12) Patent Application Publication
(10) Pub. No.: US 2002/0022137 A1
(43) Pub. Date: Feb. 21, 2002

(54) Object, particularly implant

(76) Inventor: Frank Breme, Hausen am Albis (CH)

Correspondence Address: QUARLES & BRADY LLP, 411 E. WISCONSIN AVENUE, SUITE 2040, MILWAUKEE, WI, 53202-4497, US

(21) Appl. No.: 09/861,832

(22) Filed: May 21, 2001

(30) Foreign Application Priority Data
May 27, 2000 (DE) 100 26 540.5

(51) Int. Cl. B32B 15/08; C23C 16/00; H05H 1/24

(52) U.S. Cl. 428/457; 428/670; 428/626; 428/661; 427/569; 427/255.28

(57) ABSTRACT

The invention relates to an object, particularly an implant.

The problem of the present invention is to provide an object formed from a plastic substrate and an iridium-containing coating and to make available a process permitting the production of such a composite, together with an apparatus suitable for performing the process.

The problem of the invention is solved by an object formed from a plastic body provided on its surface with a film. The film comprises at least one coating, which contains iridium.

The invention relates to an object, particularly an implant, and to a process and apparatus for the production thereof.

It is e.g. known from EP 897 997 A1 to produce an object from a composite material, which comprises a plastic substrate and a strongly adhering, thin, metal-containing coating. It is known that the metal of the metal-containing coating is selected from the group Ti, Ta, Nb, Zr and Hf. In applications in the field of implants and other materials coming into contact with blood, the metal-containing coating has the advantage of aiding body compatibility of the plastic materials. Plastic materials are used in a preferred manner in medical technology due to their advantageous mechanical characteristics. However, for certain applications body compatibility can be problematical.

It is also known from U.S. Pat. No. 5,980,566 that a coating with iridium oxide on a metallic stent reduces defensive reactions of the body tissue and leads to an improved surface structure, which creates an improved surface for the retention of healing-assisting substances. Stents are typically made from a biocompatible metal, to which can be applied an iridium oxide film.

Besides being disclosed by U.S. Pat. No. 5,980,566, processes for coating a substrate with iridium or iridium oxide are e.g. also known from the articles of M. A. El Klakani and M. Chaker, “Reactive pulsed laser deposition of iridium oxide thin films” in Thin Solid Films 335, (1998), pp 6-12 and K. Nishio, Y. Watanabe and T. Tsuchiya, “Preparation and properties of electrochromic iridium oxide thin film by sol-gel process” in Thin Solid Films 350, (1999), pp 96-100. These documents disclose that iridium-containing coatings can be produced on a substrate at temperatures above 300° C. For coating purposes use is either made of dip coating processes, in which a glass or metal substrate is dipped in an iridium oxide-containing fluid and consequently iridium oxide is deposited on the substrate, or iridium oxide can be deposited on a substrate using sputtering processes, which use temperatures between 300 and 550° C.

These processes suffer from the disadvantage that the temperature range in which they can be used is so high that plastic substrates are at least damaged during coating and do not maintain their properties. Thus, e.g. the chain length of the polymers is influenced, the plastics in part no longer being stable, whilst there can be changes in the design and other characteristics of the plastic substrate body to be coated. Therefore these processes are not suitable for the production of an object comprising a plastic substrate with an iridium-containing coating.

The problem of the present invention is to provide an object formed from a plastic substrate and an iridium-containing coating, whilst providing a process enabling such a composite to be produced, together with an apparatus suitable for performing the process.

Based on the preamble features, the problem of the invention is solved by the characterizing features of the independent claims.

The problem of the invention is solved by an object, which is formed from a plastic body and which has on its surface a film. The film comprises at least one coating and the at least one coating contains iridium.

The term iridium-containing is used to mean a coating containing metallic iridium and/or an iridium oxide, such as Ir₂O₃ or IrO₂.

According to advantageous developments the outermost coating of the film contains iridium. Preferably said coating is approximately or at least preponderantly formed from metallic iridium or iridium oxide. According to an advantageous further development the outermost coating of the film is formed from iridium and/or iridium oxide. Preference is given to developments in which the iridium-containing coating has a thickness of less than 10 μm. To achieve a considerable flexibility of the film, it is particularly advantageous for the iridium-containing coating to have a thickness of a few atomic layers and in the extreme case there is only a monoatomic coating thickness. However, preference is given to a variant in which the iridium-containing coating forms a closed coating and preferably covers the entire surface of the object. However, it is also possible for the iridium-containing coating not to form a closed coating, but instead for it to be formed from a plurality of separate islands or the iridium-containing coating has systematic or random gaps.

According to an advantageous further development, besides the iridium-containing coating, the film also has a support layer. The support layer preferably contains metal and in particular at least one of the elements Ti, Ta, Nb, Zr and Hf. To the extent that the iridium-containing coating incorporates iridium oxide, the support layer can also contain or comprise metallic iridium. Advantageously use is made of variants in which the thickness of the support layer, which is preferably formed between plastic bodies and the iridium-containing coating, is a few nanometres and in particular less than 50 nm.

Variants of the invention are advantageous in which the object comprises a plastic body, in which the plastic is a polymeric, particularly thermoplastic material, preferably PP (polypropylene), PET (polyethylene terephthalate), PU (polyurethane) or expanded PTFE (polytetrafluoroethylene). The object can also be in the form of a porous structure, particularly a preferably textile fibre material. It can in particular be an implant for the animal or human body, e.g. cardiac valves, mitral rings (annulus plastic) or a prosthesis, such as a vascular prosthesis or a partial prosthesis. The plastic body can have cavities and/or pores and/or undercuts.

A process according to the invention for the application of an iridium-containing coating on a plastic object is characterized in that the iridium-containing coating is produced by a plasma CVD process (PACVD-plasma activated chemical vapour deposition). A PACVD process is described in EP 881 197A2.

For producing an iridium oxide-containing coating, an oxygen-containing process gas atmosphere is produced when carrying out the PACVD process. The pressure of the process gas atmosphere when carrying out a PACVD process for producing an iridium oxide-containing coating is below 10 mbar, particularly approximately 1 mbar.

According to an advantageous development of the invention the iridium of the process gas atmosphere is produced by evaporating a precursor substance, which advantageously contains at least one of the elements of the group iridium (III) acetyl acetonate, iridium (I) dicarbonyl-2,4-pentane dionate, chlorocarbonyl-bis(triphenylphosphine) iridium (I) and iridium-carbonyl.

According to a preferred embodiment of the process according to the invention the process gas atmosphere temperature is chosen in such a way that it is below the temperature where thermal damage occurs to the plastic body. Thermal damage to the plastic body means both a mechanical damage and a change to the characteristics of the plastic body, e.g. with respect to shape, elasticity and stability under continuous loading, together with morphology. The highest permitted process gas atmosphere temperature is a function of the plastic forming the plastic body. The temperature is in particular in a range below 250° C., preferably below 140° C. According to a further development of the invention the process gas atmosphere temperature is higher than 80° C., particularly higher than 100° C.

According to a further development of the invention the plasma coating of the plastic body is carried out in that initially a support layer and then the iridium-containing coating is applied. It is also possible to apply the support layer by a plasma CVD process (PACVD). Preferably the plasma CVD process for applying the support layer to the plastic body is performed in an oxygen-free process gas atmosphere. Advantageously iridium or titanium, particularly titanium carbonitride is deposited as the support layer on the object. Preferably the process is developed in such a way that following the application of the support layer to the object and before the iridium-containing coating is applied, there is a waiting time in the oxygen-containing atmosphere. During said waiting time oxygen can be incorporated in the support layer, e.g. if the latter is of titanium carbonitride. According to a preferred development of the invention at least partly the radioactive isotope Ir(192) is used as iridium. As an alternative to the use of radioactive iridium, following coating, it is possible to expose the object with the iridium-containing coating to a source of radiation, particularly beta radiation and in this way transform part of the deposited iridium into the radioactive isotope Ir(192).

An apparatus according to the invention for performing the process has a reaction chamber in which a process gas atmosphere can be produced. The reaction chamber is connected to at least one evaporator for evaporating at least the iridium-containing precursor substance.

According to an advantageous development of the invention the reaction chamber has a gas supply by means of which, as desired, an oxygen-containing or an oxygen-free atmosphere can be produced in the reaction chamber. According to a further development of the invention the plasma generator is constituted by a transmitter of electromagnetic radiation, which in particular irradiates either microwaves or waves with a frequency of 13.56 MHz. According to a further development of the invention the reaction chamber is connected to two evaporators, the first evaporator serving to evaporate the precursor substance for the support layer and the second evaporator for evaporating the iridium-containing precursor substance for producing the iridium-containing coating.

The above and further features can be gathered from the claims, description and drawings and the individual features, either singly or in the form of subcombinations, can be implemented in an embodiment of the invention and in other fields and can represent advantageous, independently protectable constructions for which protection is hereby claimed. In the drawings show:

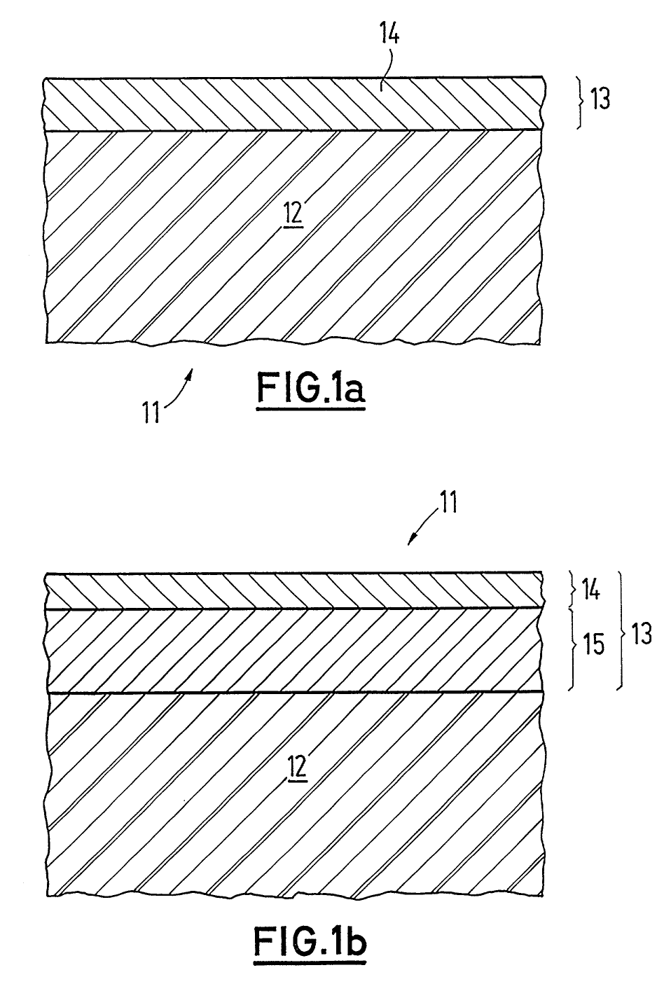

FIGS. 1a & 1b A diagrammatic representation of an object with a film according to the invention.

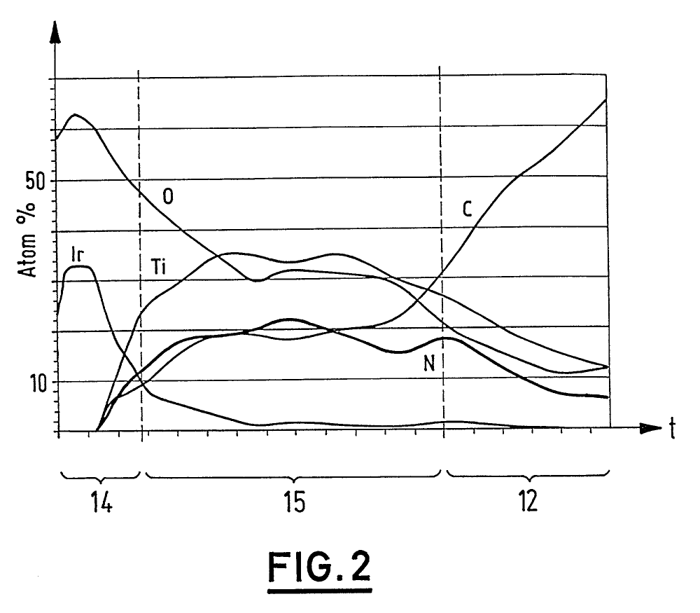

FIG. 2 A XPS analysis of the film as a function of the coating depth.

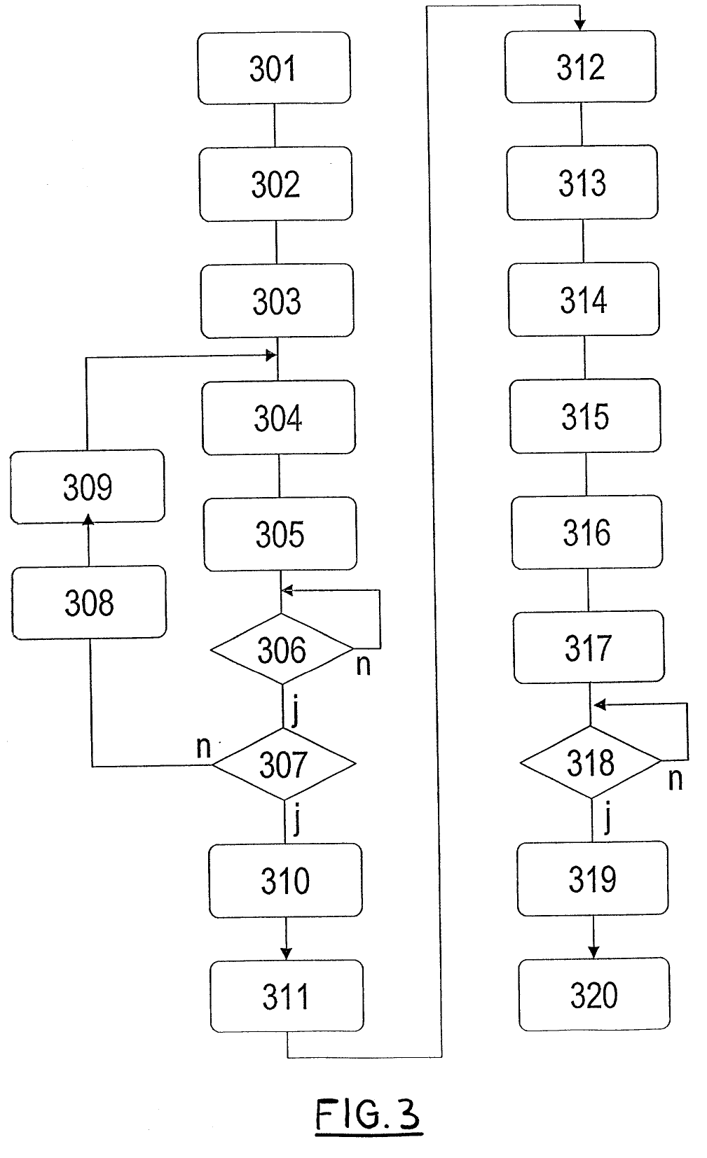

FIG. 3 A flow chart of a process according to the invention.

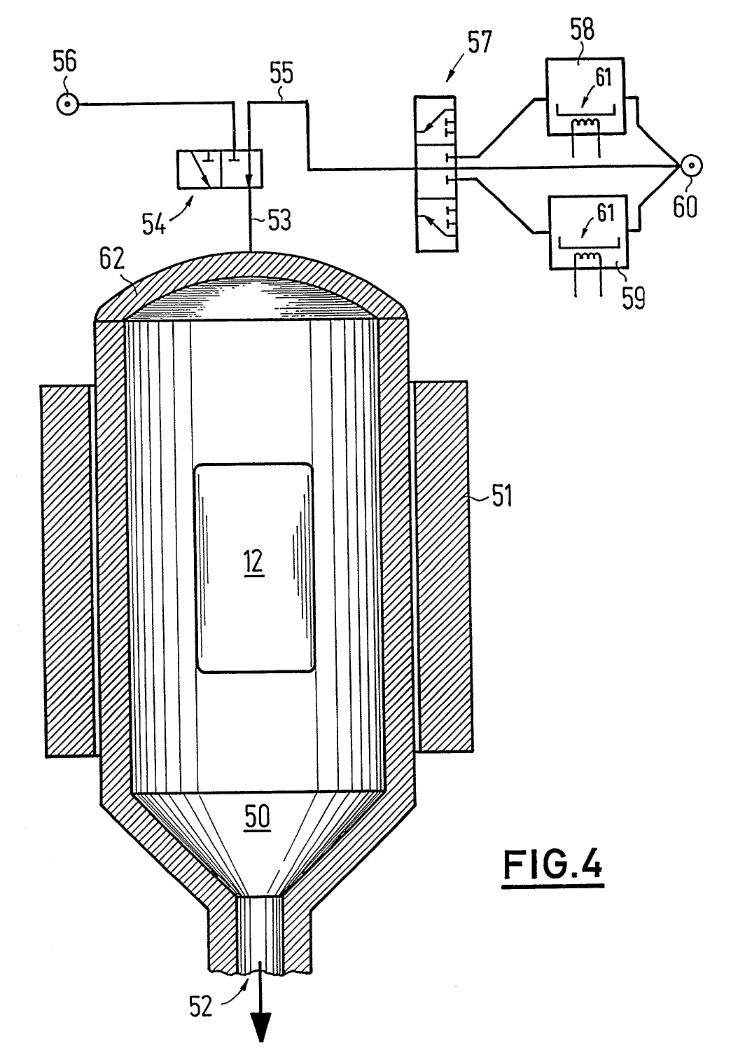

FIG. 4 Diagrammatically an apparatus according to the invention for performing the process according to the invention.

FIG. 1a diagrammatically shows a section through an object 11 according to the invention. The object 11 comprises a plastic body 12 and has the film 13, which comprises a coating in the form of an iridium-containing coating 14.

FIG. 1b also diagrammatically shows a section through an object according to the invention. This object 11 also comprises a plastic body 12 and a film 13. However, here the film 13 is formed from two coatings, namely the outer, iridium-containing coating 14 and the support layer 15, which is formed between the iridium-containing coating 14 and the plastic body 12.

In both embodiments the iridium-containing coating can be formed either from pure iridium and/or an iridium oxide, such as IrO₂ or Ir₂O₃. The iridium-containing coating contains e.g. at least 50% iridium or iridium oxide. The iridium or iridium oxide percentage can rise to 100% of the coating forming agent, so that a coating is formed of pure iridium or pure iridium oxide. It is possible for part of the iridium to comprise the radioactive isotope Ir(192). The use of a low concentration of the radioactive isotope has the advantage that no deposits are formed in the case of blood contact on the surface, so that e.g. in the case of vascular implants the thrombosis risk is reduced. As a result of the radioactivity the radioactive isotope of iridium has within a period of six months largely decayed, so that there is only a temporary, as opposed to permanent stressing of the environment. The iridium-containing coating preferably forms a closed coating. However, it is also possible for the iridium-containing coating not to be closed and instead for there to be iridium-containing islands or coating-free gaps. The thickness of the iridium-containing coating is usually lower than 10 μm. It is in particular in a range of a few nanometres and can be reduced down to a monoatomic coating thickness. With the process according to the invention it is e.g. also possible to produce coating thicknesses of approximately 5 nm. Such limited coating thicknesses are in particular advantageous if the plastic body 12 is flexible instead of stiff and the film 13 on the plastic body influences the mechanical characteristics thereof with respect to flexibility to a minimum extent, but still adheres well.

As plastic bodies use can be made of bodies from numerous different plastic types, but in particular PET, PP, PU or PTFE. The plastic body need not necessarily be a monolithic body. It is in fact possible for it to be a body comprising a fibrous material or a textile material and it can have cavities and undercuts. Such bodies are e.g. used as implants, including those which are in long-term contact with the blood. Examples are vascular prostheses, together with cardiac valves, mitral rings (annulus plastic) and long-term catheters in contact with the blood. In the case of all these implants the coating with iridium ensures an improved blood compatibility.

The support layer 15 shown in FIG. 1b can be formed either from iridium, in the case that the iridium-containing coating is formed from iridium oxide, or from another metal-containing coating. It is in particular possible to use coatings containing Ti, Hf, Ta, Nb and Zr. It is possible for one or more metals from said group to be present in the support layer. It is simultaneously possible for the support layer to also contain carbon, nitrogen and oxygen. The function of the support layer is to ensure a good connection between the plastic body 12 and iridium-containing coating 14. To ensure that there are no significant changes to the mechanical characteristics of the plastic body 12, the support layer will have the smallest possible thickness. Thicknesses which are below 50 nm are particularly suitable. As the support layer use can be made of layers and coatings of the type described e.g. in EP 897 997 A1.

Apart from the aforementioned materials the plastic substrate, i.e. the plastic body material can be of polyethylene terephthalate (PET), polyurethane (PUR), polytetrafluoroethylene (PTFE) and polypropylene (PP), as well as polyamide (PA), polyether ketone (PEK), polysulphone (PSU), polybutylene terephthalate (PBT), polyether sulphone (PES), polyimide (PI), polycarbonate (PC), polyether imide (PEI), polyamide imide (PAI), etc., or silicones. All these plastics are stable at a temperature below 250° C. to the extent that there is no thermal damage. Thermal damage is understood to mean both mechanical damage and a modification to characteristics, particularly the physical characteristics of the plastic body. The permitted maximum temperature for a film is a function of the plastic used. For example in the case of PU it is 100° C., PP 135° C., PET 150° C. and PTFE up to 250° C. without thermal damage occurring. The process according to the invention is suitable for coating all these substances without there being any mechanical damage to the plastic body.

FIG. 2 shows the coating compositions of the object, as determined by XPS (X-ray photoelectron spectroscopy). The depth profiles are recorded by sputtering the coatings with AR⁺. An object 11 was investigated, which comprised a plastic body 12 and a film 13, which has both an iridium-containing coating and a support layer.

Since when investigating using sputtering processes initially the outer coatings are removed, initially the iridium-containing coating 14 is considered. In the vicinity of the iridium-containing coating 14 the investigated sample, according to the results shown, comprises one third iridium and two thirds oxygen. Thus, the iridium-containing coating 14 was formed from IrO₂. After removing the iridium-containing coating 14 it is possible to see the support layer 15. Essential constituents of said support layer are titanium (Ti), nitrogen (N) and oxygen (0). In the selected example the support layer 15 consequently consisted of titanium carbonitride. As opposed to this the main constituent of the plastic body 12 is carbon (C), which is already present in the support layer 15.

FIG. 3 is a flow chart of an exemplified process for the production of an object according to the invention.

Steps 301 to 312 reproduce the support laye production process. A process for the production of a suitable support layer and the process conditions can e.g. be gathered from EP 897 997 A1. Slight differences compared with the process represented therein are covered. They preferably comprise the support layer being applied in several cycles, a new process gas atmosphere being produced between each cycle. Prior to producing the new process gas atmosphere it can be appropriate to evacuate the spent or used atmosphere and then carry out a scavenging process with process gas-free atmosphere. Such a cyclic process offers the advantage that a reliable and more uniform coating can be obtained, even when undercuts and cavities are present.

The application of the support layer, like the production of the iridium-containing coating, takes place by means of a plasma CVD process (PACVD), i.e. a chemical vapour deposition process, in which a plasma is produced in the process gas by means of an external energy source. The plasma can be produced or generated by e.g. radio frequency methods, particularly in the frequency range of 13.56 MHz or by microwaves.

If the iridium-containing coating is applied directly to the plastic body, i.e. if no support layer is required, it is possible to omit process steps 302 to 313.

According to step 301 the plastic body, the substrate for the deposition of the support layer or iridium-containing coating by the plasma CVD process can be introduced into the reaction chamber, which is then evacuated and scavenged in step 302. During scavenging both an oxygen-containing atmosphere and an oxygen-free atmosphere can be produced in the reaction chamber, depending on whether it is desirable to deposit an oxygen-containing coating or an oxygen-free coating on the substrate. Following the scavenging of the reaction chamber, the process temperature is controlled in step 303. The possible process temperature is a function of the temperature at which mechanical damage occurs to the plastic body. Deposition will take place below this temperature, i.e. use will be made of a temperature range of approximately 80° C. to approximately 250° C., as a function of the plastic body material. Then, in step 304, the process gas is fed into the reaction chamber. This generally takes place by evaporating a precursor substance and by introducing the evaporated precursor substance into the reaction chamber atmosphere. Feeding in of the process gas continues until a suitable precursor substance concentration is contained in the atmosphere. Then, in step 305, the plasma is ignited and use is made for this purpose of the external energy source, e.g. the microwave transmitter.

Waiting takes place in step 306 until the plasma burning time reaches a desired value. The value is selected so as to ensure that at all times during plasma generation coating forming agents are still present at all points.

On reaching the burning time of a burning cycle, according to step 307 it is monitored to establish whether the number of plasma generations performed is sufficient to produce the desired coating thickness on the plastic body. The coating thicknesses are in particular in the range lower than 1 μm, particularly lower than 50 nm. If an adequate coating thickness has still not been produced, there is initially a passage to steps 308 and 309, followed by a jump back to step 304.

According to step 308 the atmosphere in the reaction chamber is initially evacuated and then scavenged according to step 309 and intermediately it is possible to produce a very high pressure atmosphere (higher than 10 mbar). As a result a state is produced in the reaction chamber which corresponds to that after process step 303. By feeding in process gas, i.e. by again evaporating the precursor substance, it is again possible to produce the process gas atmosphere according to step 304, to which there has been a jump back. By cyclically repeating the scavenging and production of the starting process gas atmosphere it is ensured that at all points, i.e. also in the vicinity of undercuts and pores in the plastic body, a coating with support substance is obtained.

If it was found in step 307 that an adequate support layer thickness had been obtained, there is a passage to steps 303 to 312.

According to step 310 the reaction chamber is vented and then, in step 311, the plastic body is removed from the reaction chamber. According to step 312 there is a waiting time in oxygen-containing atmosphere if it is desired that oxygen be incorporated into the support layer, e.g. as described in EP 897 997 A1. If oxygen incorporation is to be avoided, steps 311 to 313 can be omitted and step 314 can follow directly onto step 310. The venting of the reaction chamber in step 310 merely serves as a scavenging process, which is in particular necessary if there is to be a passage from an oxygen-free process gas atmosphere to an oxygen-containing process gas atmosphere. An oxygen-containing process gas atmosphere is more particularly necessary for producing iridium oxide coatings, i.e. coatings of IrO₂ or Ir₂O₃.

Then, according to steps 313 to 320, the iridium-containing coating 14 is produced. The process steps 313 to 320 are described relative to an example for coating a polyethylene terephthalate (PET) plastic body, e.g. a vascular prosthesis. It was e.g. provided in accordance with process steps 301 to 312 with a support layer with a thickness of e.g. 50 nm and which contains titanium, but which can also incorporate carbon, nitrogen and oxygen. It can in particular be a titanium carbonitride support layer.

According to step 313, the plastic body to be coated, i.e. the vascular prosthesis to be coated, is introduced into the reactor and the latter is heated to the process temperature of e.g. 120° C. There is no thermal damage to the plastic body at this temperature. Then and in accordance with step 314 evacuation takes place to a pressure of approximately 0.02 mbar. According to step 315 the reaction chamber is then scavenged with air for 60 seconds at approx. 1 mbar.

Then air is passed through the evaporator, so that process gas is fed in in accordance with step 316. It is a precursor substance, which is evaporated in the evaporator, which is e.g. heated to 140° C. The air flowing through the evaporator is filled with iridium-containing precursor substance. The precursor substance is e.g. iridium (III) acetyl acetonate, but can also be iridium (I) dicarbonyl-2,4-pentane dionate, chlorocarbonyl-bis(triphenylphosphine) iridium (I) or iridium-carbonyl. The charging or filling of the air supplied to the process chamber can e.g. be approx. 4×10⁻³ mole of precursor substance per mole of air. The charged gas passes into the reactor and the latter is e.g. scavenged for about 30 seconds with said gas, so that a uniform process gas atmosphere is produced in the reactor. The reactor pressure is approximately 1 mbar.

In step 317 the plasma is ignited by coupling electromagnetic waves into the reaction chamber. It can e.g. be a radio frequency in the range of 13.56 MHz. It is also possible to generate a plasma by microwave radiation. Through the production of the plasma a reaction occurs and an iridium oxide coating is deposited. According to step 318 the plasma is maintained until the desired burning time of e.g. approx. 5 minutes is obtained. During such a burning time an iridium-containing coating with a thickness of e.g. 5 nm is produced. If a larger iridium-containing coating thickness is desired, in corresponding to the support layer production process steps 304 to 309 greater coating thicknesses can be obtained by repeating steps 314 to 318. Alternatively or additionally it is possible to increase the burning time. In accordance with steps 304 to 309 it can be advantageous if the old atmosphere, which has survived a plasma burning process, is initially evacuated, e.g. according to step 314.

After producing an adequate thickness of the iridium-containing coating, according to steps 319 the reactor is vented and then, according to step 320, the object if not already having a support layer, but at least having an iridium-containing coating, is removed from the reaction chamber.

FIG. 4 shows an apparatus for performing a process according to the invention, particularly which contains process steps 301 to 320, in a diagrammatic form. The plastic body 12 is introduced into the reaction chamber 50. In the vicinity of the introduction point of the plastic body 12, outside the reaction chamber 50 is located the plasma generator 51, particularly an electromagnetic wave transmitter, e.g. an induction coil. The reaction chamber 50 is evacuated by means of the air vent 52. For this purpose suitable pumps are connected by suitable lines to the air vent 52. As a result of evacuation by means of the air vent 52, the pressure e.g. necessary for plasma generation is maintained during the plasma process.

For charging the reaction chamber with a corresponding atmosphere a gas supply 53 is provided. The gas supply 53 can be connected, e.g. via the control valve 54, as desired, either to an air supply 55 or some other gas source (e.g. H₂). The other gas source 56 is in particular used for producing an oxygen-free atmosphere in the reaction chamber. The air supply 55 is used for producing a suitable process gas atmosphere and by means of the 3/1 control valve 57, as desired, gas can be supplied directly from the first evaporator 58 or the second evaporator 59 or directly from the gas source 60 to the reaction chamber 50. Generally, in the first reaction chamber evaporation takes place through the evaporator 61 of the precursor substance of the coating forming agent for the support layer and is then supplied to the reaction chamber. The second reaction chamber 59 contains the heating element 61 for evaporating the precursor substance for the coating forming agent of the iridium-containing coating. For example, for producing an oxygen-free atmosphere in the reaction chamber, in place of air, it is possible to use some other gas such as H₂ or He at the gas source 60. This is advantageous for producing the support layer and an oxygen-free iridium coating.

If the gas source 60 supplies gas at a specific pressure to the two evaporators 58, 59 and directly to the 3/1 control valve 57, then through the control position of the latter it is possible to determine which gas or which process gas is supplied to the reaction chamber. Thus, a scavenging process can be carried out in the same way as the coating with the support layer or the coating with the iridium-containing coating. It is not absolutely necessary for the plastic body to be removed from the reaction chamber when changing the coating type or for scavenging processes. This avoids contaminants, which are undesired, reaching the plastic body 12 between the production of the individual coatings. So that the coated plastic body 12 can be removed from the reaction chamber 50 on ending the process and can be introduced into the reaction chamber 50 for coating purposes, said chamber 50 has a removable lid 62.

1. Object, particularly implant, comprising a plastic body having on its surface a film, which comprises at least one coating, wherein the at least one coating (14) contains iridium.

2. Object according to claim 1, wherein the iridium-containing coating (14) of the film (13) is its outermost coating.

3. Object according to claim 1, wherein one of the member of the group consisting of iridium-containing coating (14) at least preponderantly contains iridium oxide and iridium.

4. Object according to claim 3, wherein the iridium containing coating comprises at least one member of the group of iridium oxide and iridium.

5. Object according to claim 1, wherein the iridium of the iridium-containing coating (14) contains the isotope Ir(192).

6. Object according to claim 1, wherein the iridium-containing coating (14) of the film (13) has a thickness of less than 10 μm.

7. Object according to claim 6, wherein the iridium-containing coating (14) of the film (13) has a monoatomic thickness.

8. Object according to claim 1, wherein the iridium-containing coating (14) is a closed coating covering the entire surface of the object.

9. Object according to claim 1, wherein between the plastic body (12) and the iridium-containing coating (14) is formed a support layer (15).

10. Object according to claim 9, wherein the support layer contains metal.

11. Object according to claim 10, wherein the metal is at least one member of the group consisting of the elements Ti, Ta, Nb, Zr and Hf.

12. Object according to claim 9, wherein the support layer (15) contains metallic iridium and the iridium-containing coating (14) contains iridium oxide.

13. Object according to claim 9, wherein the support layer (15) of the film (13) has a thickness of a few nanometres.

14. Object according to claim 1, wherein the plastic of the plastic body (12) is at least one member of the group consisting of a polymeric plastic, PP, PET, PU, PTFE, and expanded PTFE.

15. Object according to claim 1, wherein the plastic body (12) has at least one of the following features: cavities, pores and undercuts.

16. Object according to claim 1, wherein the plastic body (12) is a porous structure.

17. Object according to claim 16, wherein the plastic body (12) is textile fibre material.

18. Object according to claim 1, wherein the object (11) is an implant for the animal or human body.

19. Object according to claim 18, wherein the object is one element of the group consisting of a prosthesis, vascular prothesis and partial prothesis.

20. Process for the application of an iridium-containing coating (14) to an object (11), which has a plastic body (12) with a film (13) on its surface, said film (13) comprising at least one coating, wherein an iridium-containing coating is produced by a plasma CVD process.

21. Process according to claim 20, wherein the iridium-containing coating is produced in a process gas atmosphere having a pressure of less than 10 mbar.

22. Process according to claim 20, wherein the iridium-containing coating is produced in a process gas atmosphere containing oxygene.

23. Process according to claim 20, wherein the process gas atmosphere contains iridium and is produced by evaporating an iridium-containing precursor substance.

24. Process according to claim 23, wherein the precursor substance is at least one member of the group consisting of iridium (III) acteyl acetonate, iridium (I) dicarbonyl1-2,4-pentane dionate, chlorocarbonyl-bis (triphenyl phosphine) iridium (I) or iridium-carbonyl.

25. Process according to claim 20, wherein the coating temperature is chosen in such a way that there is no thermal damage to the plastic body (12).

26. Process according to claim 25, wherein the process gas atmosphere temperature is lower than 200° C.

27. Process according to claim 20, wherein the process gas atmosphere exceeds 80° C.

28. Process according to claim 20, wherein the film (13) comprises a support layer (15) and an iridium-containing coating (14), initially the support layer (15) is applied to the plastic body (12).

29. Process according to claim 28, wherein the application of the support layer (15) takes place by means of a plasma CVD process.

30. Process according to claim 29, wherein the plasma CVD process is carried out in an oxygen-free process gas atmosphere.

31. Process according to claim 28, wherein the support layer (15) deposition takes place on the object by deposition of at least one member of the group consisting of titanium, titanium carbonitrides and iridium.

32. Process according to claim 28, wherein between the application of the support layer (15) and the application of the iridium-containing coating (14) there is a waiting time in the oxygen-containing atmosphere.

33. Process according to claim 20, wherein the radioactive isotope Ir(192) is at least partly used as iridium.

34. Apparatus for performing a process according to claim 20, wherein the apparatus has a reaction chamber (50), in which there is a plasma generator (51) for generating a plasma in said reaction chamber (50) and in which the reaction chamber (50) is connected to at least one evaporator, which is constructed for evaporating at least one iridium-containing precursor substance.

35. Apparatus for performing a process according to claim 34, wherein the plasma generator (51) is an electromagnetic radiation transmitter.

36. Apparatus according to claim 34, wherein the reaction chamber (50) has a gas supply making it possible to produce either an oxygen-containing or an oxygen-free atmosphere in the reaction chamber (50).

37. Apparatus according to claim 34, wherein there is a first evaporator (58) for evaporating a first precursor substance for coating the plastic body (12) with a support layer (15) and a second evaporator (19) for evaporating a second, iridium-containing precursor substance for coating the plastic body (12) with the iridium-containing coating (14).

38. Apparatus according to claim 37, wherein the iridium-containing substance contains iridium oxide.
